(19) United States
(12) Patent Application Publication
(10) Pub. No.: US 2012/0028459 A1
(43) Pub. Date: Feb. 2, 2012

(54) MANUFACTURING PROCESS OF CIRCUIT SUBSTRATE

(75) Inventors: Yu-Yong Lee, Kyunggi-Do (KR); Sung-Mo Kang, Kyunggi-Do (KR); Soon-Heung Bae, Kyunggi-Do (KR); Chang-Suk Han, Kyunggi-Do (KR)

(73) Assignee: ADVANCED SEMICONDUCTOR ENGINEERING, INC., Kaohsiung (TW)

(21) Appl. No.: 12/873,540

(22) Filed: Sep. 1, 2010

(30) Foreign Application Priority Data
Jul. 29, 2010 (TW) 99125144

(51) Int. Cl. H01L 21/768

(52) U.S. Cl. 438/637; 257/E21.586

(57) ABSTRACT

A manufacturing process of a circuit substrate is provided. A conductive structure including a first patterned conductive layer, a first dielectric layer, a second dielectric layer, a first conductive layer, and a second conductive layer is provided. The first dielectric layer and the second dielectric layer are respectively disposed on two opposite surfaces of the first patterned conductive layer. The first conductive layer and the second conductive layer are respectively disposed on the first dielectric layer and the second dielectric layer. The first dielectric layer is between the first patterned conductive layer and the first conductive layer. The second dielectric layer is between the first patterned conductive layer and the second conductive layer. A conductive via is formed at the conductive structure. The first conductive layer and the second conductive layer are patterned to respectively form a second patterned conductive layer and a third patterned conductive layer.

### CROSS-REFERENCE TO RELATED APPLICATION

This application claims the priority benefit of Taiwan application serial no. 99125144, filed on Jul. 29, 2010. The entirety of the above-mentioned patent application is hereby incorporated by reference herein and made a part of specification.

### BACKGROUND OF THE INVENTION

1. Field of the Invention

The present invention generally relates to a manufacturing process of an electronic component, and more particularly, to a manufacturing process of a circuit substrate.

2. Description of Related Art

Circuit substrate is one of the most commonly used components in today's semiconductor packaging technology. A circuit substrate is formed by alternatively stacking a plurality of patterned conductive layers and a plurality of dielectric layers, wherein every two patterned conductive layers may be electrically connected with each other through a conductive via. How to effectively simplify the manufacturing process of circuit substrate has become one of the major subjects along with the increase in the circuit density of circuit substrate.

### SUMMARY OF THE INVENTION

Accordingly, the present invention is directed to a circuit substrate manufacturing process with reduced manufacturing time.

The present invention provides a circuit substrate manufacturing process. First, a conductive structure is provided. The conductive structure includes a first patterned conductive layer, a first dielectric layer, a second dielectric layer, a first conductive layer, and a second conductive layer. The first dielectric layer and the second dielectric layer are respectively disposed on two opposite surfaces of the first patterned conductive layer. The first conductive layer and the second conductive layer are respectively disposed on the first dielectric layer and the second dielectric layer, wherein the first dielectric layer is between the first patterned conductive layer and the first conductive layer, and the second dielectric layer is between the first patterned conductive layer and the second conductive layer. Then, a conductive via is formed at the conductive structure, wherein the conductive via electrically connects at least two of the first patterned conductive layer, the first conductive layer, and the second conductive layer. Next, the first conductive layer and the second conductive layer are patterned to respectively form a second patterned conductive layer and a third patterned conductive layer.

As described above, in the circuit substrate manufacturing process provided by the present invention, a conductive structure having a patterned conductive layer is first provided, and then a conductive via is formed at the conductive structure and conductive layers on the surfaces of the conductive structure are patterned. Thereby, the manufacturing process is simplified and the manufacturing time is shortened.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1F is a flowchart of a circuit substrate manufacturing process according to an embodiment of the present invention.

FIGS. 2A-2E is a flowchart of a circuit substrate manufacturing process according to another embodiment of the present invention.

FIGS. 3A-3C is a flowchart illustrating some steps in a circuit substrate manufacturing process according to another embodiment of the present invention.

FIGS. 4A-4F is a flowchart of a circuit substrate manufacturing process according to another embodiment of the present invention.

FIG. 5, FIG. 6, and FIG. 7 are respectively top views of FIG. 4B, FIG. 4D, and FIG. 4F.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

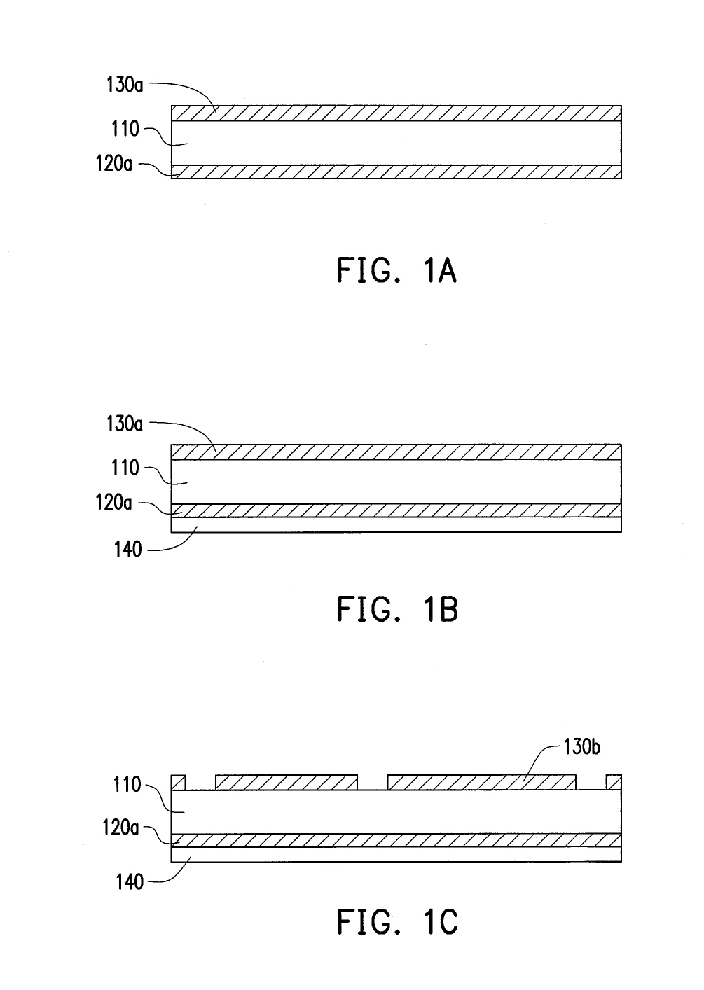

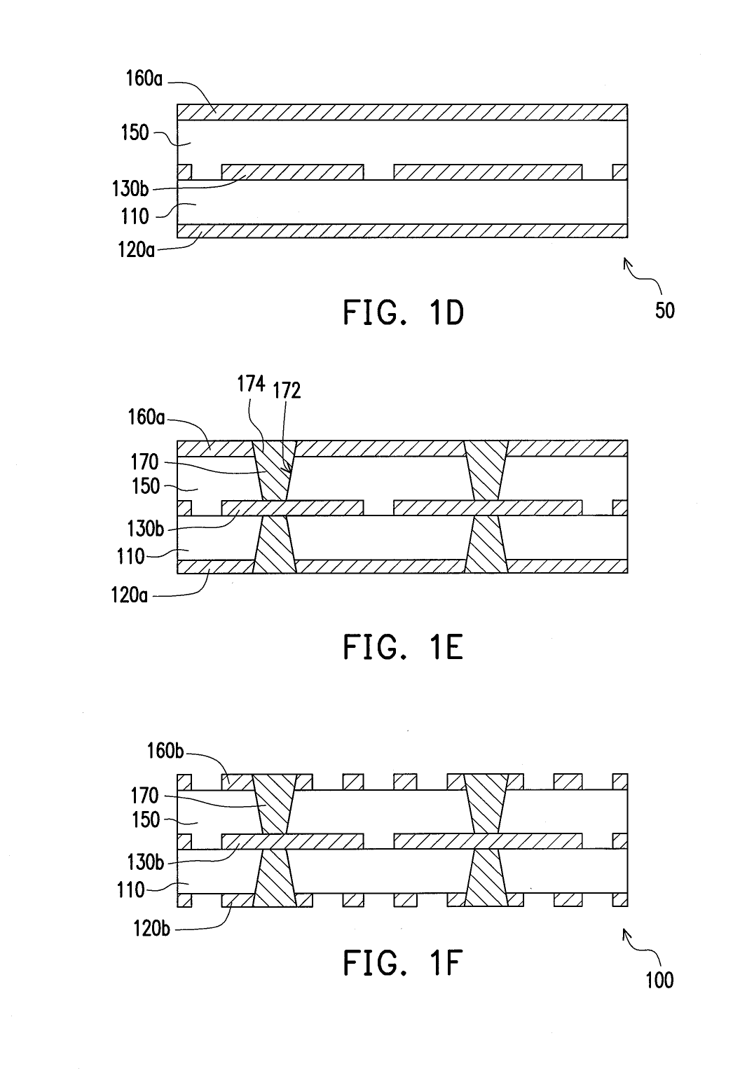

FIGS. 1A-1F is a flowchart of a circuit substrate manufacturing process according to an embodiment of the present invention. First, referring to FIG. 1A, a first dielectric layer 110, a first conductive layer 120a, and a third conductive layer 130a are provided, wherein the first conductive layer 120a and the third conductive layer 130a are respectively disposed on two opposite surfaces of the first dielectric layer 110. Referring to FIG. 1B, a mask layer 140 is formed to cover the first conductive layer 120a. Referring to FIG. 3C, the third conductive layer 130a is patterned to form a first patterned conductive layer 130b.

Then, referring to FIG. 1D, after the first patterned conductive layer 130b is formed, the mask layer 140 is removed, and a second dielectric layer 150 and a second conductive layer 160a are formed on the first patterned conductive layer 130b, so that the first patterned conductive layer 130b is between the first dielectric layer 110 and the second dielectric layer 150, and the second dielectric layer 150 is between the second conductive layer 160a and the first patterned conductive layer 130b.

A conductive structure 50 is formed through foregoing steps. The conductive structure 50 includes the first patterned conductive layer 130b, the first dielectric layer 110, the second dielectric layer 150, the first conductive layer 120a, and the second conductive layer 160a. The first dielectric layer 110 and the second dielectric layer 150 are respectively disposed on two opposite surfaces of the first patterned conductive layer 130b. The first conductive layer 120a and the second conductive layer 160a are respectively disposed on the first dielectric layer 110 and the second dielectric layer 150, wherein the first dielectric layer 110 is between the first patterned conductive layer 130b and the first conductive layer 120a, and the second dielectric layer 150 is between the first patterned conductive layer 130b and the second conductive layer 160a.

Referring to FIG. 1E, conductive vias 170 (four as illustrated) are formed at the conductive structure 50 (as shown in FIG. 1D), wherein the conductive vias 170 electrically connect at least two of the first patterned conductive layer 130b, the first conductive layer 120a, and the second conductive layer 160a. In the present embodiment, some of the conductive vias 170 (two as illustrated) are extended from the first conductive layer 120a to the first patterned conductive layer 130b via the first dielectric layer 110 to electrically connect the first conductive layer 120a and the first patterned conductive layer 130b, and the rest conductive vias 170 (two as illustrated) are extended from the second conductive layer 160a to the first patterned conductive layer 130b via the second dielectric layer 150 to electrically connect the second conductive layer 160a and the first patterned conductive layer 130b.

To be specific, the conductive vias 170 illustrated in FIG. 1E may be formed by first forming a blind hole 172 at the conductive structure 50 (as shown in FIG. 1D) and then electroplating a metal layer 174 on the internal wall of the blind hole 172. The pattern of the conductive vias 170 is not limited in the present invention, and in another embodiment, the conductive vias 170 may also be extended from the first conductive layer 120a to the second conductive layer 160a via the first dielectric layer 110, the first patterned conductive layer 130b, and the second dielectric layer 150 to electrically connect the first conductive layer 120a, the second conductive layer 160a, and the first patterned conductive layer 130b.

Referring to FIG. 1F, the first conductive layer 120a and the second conductive layer 160a are patterned to respectively form a second patterned conductive layer 120b and a third patterned conductive layer 160b, so as to complete the manufacturing process of a circuit substrate 100. The circuit substrate 100 includes the first patterned conductive layer 130b, the first dielectric layer 110, the second dielectric layer 150, the second patterned conductive layer 120b, the third patterned conductive layer 160b, and the conductive vias 170.

The first dielectric layer 110 and the second dielectric layer 150 are respectively disposed on two opposite surfaces of the first patterned conductive layer 130b. The second patterned conductive layer 120b and the third patterned conductive layer 160b are respectively disposed on the first dielectric layer 110 and the second dielectric layer 150, wherein the first dielectric layer 110 is between the first patterned conductive layer 130b and the second patterned conductive layer 120b, and the second dielectric layer 150 is between the first patterned conductive layer 130b and the third patterned conductive layer 160b.

Some of the conductive vias 170 (two as illustrated) are extended from the second patterned conductive layer 120b to the first patterned conductive layer 130b via the first dielectric layer 110 to electrically connect the second patterned conductive layer 120b and the first patterned conductive layer 130b, and the rest conductive vias 170 (two as illustrated) are extended from the third patterned conductive layer 160b to the first patterned conductive layer 130b via the second dielectric layer 150 to electrically connect the third patterned conductive layer 160b and the first patterned conductive layer 130b.

In the present embodiment, the material of the first dielectric layer 110 may be cured resin, and the material of the second dielectric layer 150 may be semi-cured resin. In addition, the material of the first patterned conductive layer 130b, the second patterned conductive layer 120b, and the third patterned conductive layer 160b may be copper.

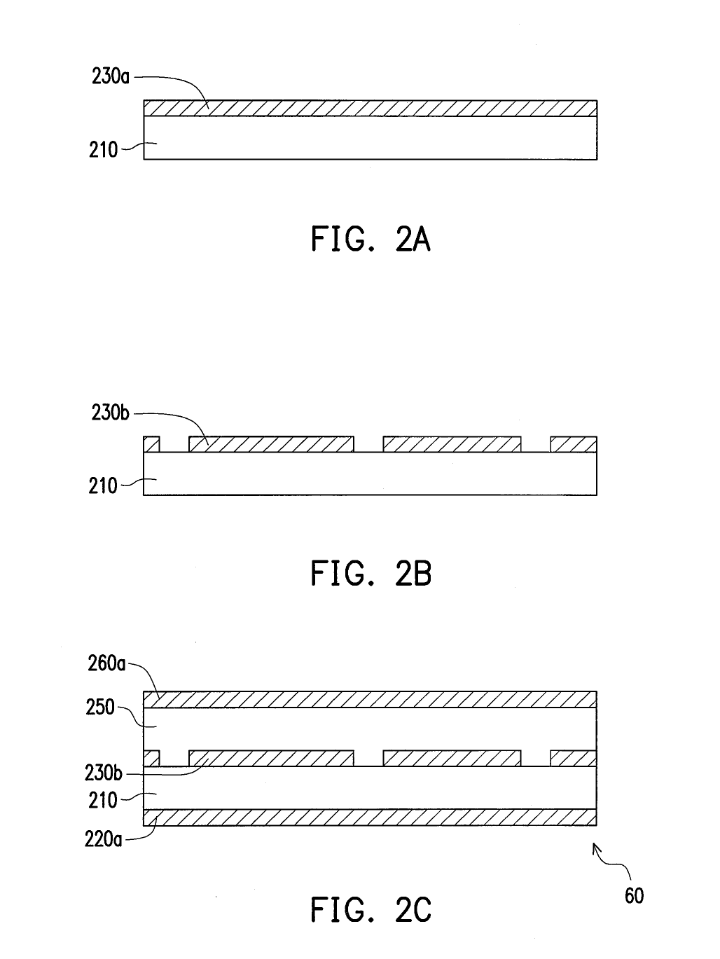

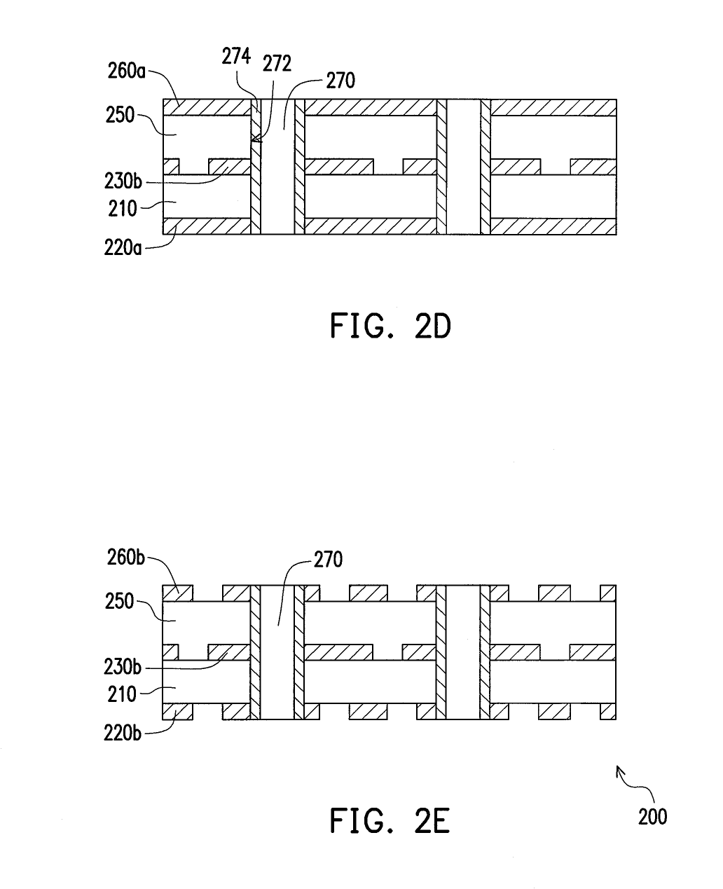

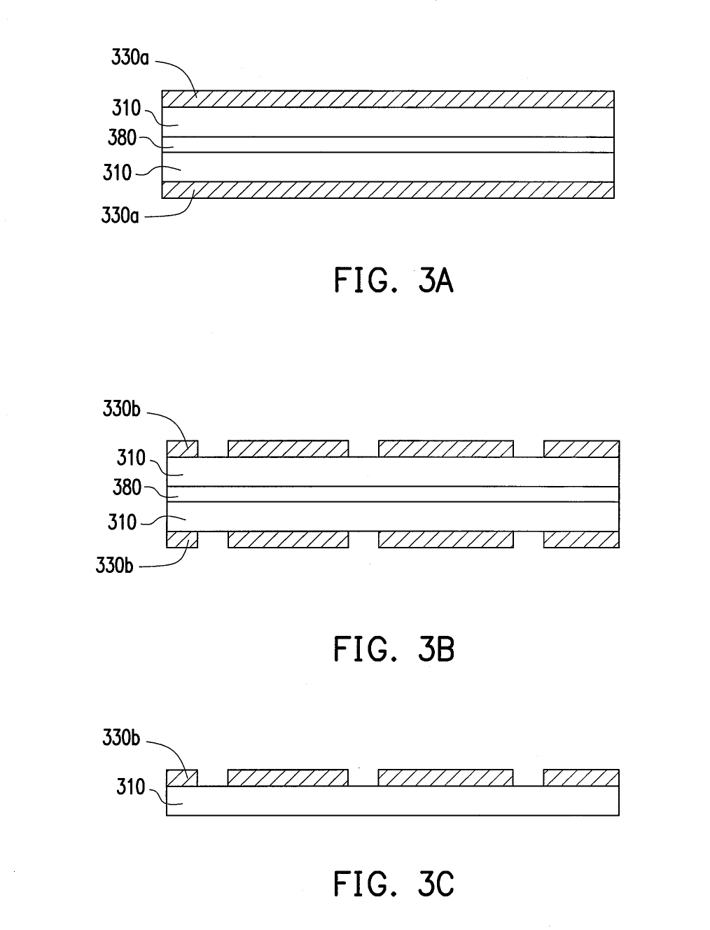

FIGS. 2A-2E is a flowchart of a circuit substrate manufacturing process according to another embodiment of the present invention. First, referring to FIG. 2A, a first dielectric layer 210 and a third conductive layer 230a are provided, wherein the third conductive layer 230a is disposed on the first dielectric layer 210. Referring to FIG. 2B, the third conductive layer 230a is patterned to form a first patterned conductive layer 230b.

Then, referring to FIG. 2C, a first conductive layer 220a is formed on the first dielectric layer 210, and a second dielectric layer 250 and a second conductive layer 260a are formed on the first patterned conductive layer 230b, so that the first dielectric layer 210 is between the first patterned conductive layer 230b and the first conductive layer 220a, the first patterned conductive layer 230b is between the first dielectric layer 210 and the second dielectric layer 250, and the second dielectric layer 250 is between the first patterned conductive layer 230b and the second conductive layer 260a.

A conductive structure 60 is formed through foregoing steps. The conductive structure 60 includes the first patterned conductive layer 230b, the first dielectric layer 210, the second dielectric layer 250, the first conductive layer 220a, and the second conductive layer 260a. The first dielectric layer 210 and the second dielectric layer 250 are respectively disposed on two opposite surfaces of the first patterned conductive layer 230b. The first conductive layer 220a and the second conductive layer 260a are respectively disposed on the first dielectric layer 210 and the second dielectric layer 250, wherein the first dielectric layer 210 is between the first patterned conductive layer 230b and the first conductive layer 220a, and the second dielectric layer 250 is located between the first patterned conductive layer 230b and the second conductive layer 260a.

Referring to FIG. 2D, conductive vias 270 (two as illustrated) are formed at the conductive structure 60 (as shown in FIG. 2C), wherein the conductive vias 270 electrically connect at least two of the first patterned conductive layer 230b, the first conductive layer 220a, and the second conductive layer 260a. In the present embodiment, the conductive vias 270 are extended from the first conductive layer 220a to the second conductive layer 260a via the first dielectric layer 210, the first patterned conductive layer 230b, and the second dielectric layer 250 to electrically connect the first conductive layer 220a, the second conductive layer 260a, and the first patterned conductive layer 230b.

To be specific, the conductive vias 270 illustrated in FIG. 2D may be formed by first forming a through hole 272 at the conductive structure 60 (as shown in FIG. 2C) and then electroplating a metal layer 274 on the internal wall of the through hole 272. The pattern of the conductive vias 270 is not limited in the present invention, and in another embodiment, the conductive vias 270 may also be extended from the first conductive layer 220a to the first patterned conductive layer 230b via the first dielectric layer 210 but not extended to the second conductive layer 260a, so as to electrically connect the first conductive layer 220a and the first patterned conductive layer 230b. The conductive vias 270 may also be extended from the second conductive layer 260a to the first patterned conductive layer 230b via the second dielectric layer 250 but not extended to the first conductive layer 220a, so as to electrically connect the second conductive layer 260a and the first patterned conductive layer 230b.

Referring to FIG. 2E, the first conductive layer 220a and the second conductive layer 260a are patterned to respectively form a second patterned conductive layer 220b and a third patterned conductive layer 260b, so as to complete the manufacturing process of a circuit substrate 200. The circuit substrate 200 includes the first patterned conductive layer 230b, the first dielectric layer 210, the second dielectric layer 250, the second patterned conductive layer 220b, the third patterned conductive layer 260b, and the conductive vias 270.

The first dielectric layer 210 and the second dielectric layer 250 are respectively disposed on two opposite surfaces of the first patterned conductive layer 230b. The second patterned conductive layer 220b and the third patterned conductive layer 260b are respectively disposed on the first dielectric layer 210 and the second dielectric layer 250, wherein the first dielectric layer 210 is between the first patterned conductive layer 230b and the second patterned conductive layer 220b, and the second dielectric layer 250 is between the first patterned conductive layer 230b and the third patterned conductive layer 260b.

The conductive vias 270 are extended from the second patterned conductive layer 220b to the third patterned conductive layer 260b via the first dielectric layer 210, the first patterned conductive layer 230b, and the second dielectric layer 250 to electrically connect the second patterned conductive layer 220b, the third patterned conductive layer 260b, and the first patterned conductive layer 230b.

In the present embodiment, the material of the first dielectric layer 210 may be cured resin, and the material of the second dielectric layer 250 may be semi-cured resin. However, in another embodiment, the material of the first dielectric layer 210 may also be semi-cured resin. Besides, the material of the first patterned conductive layer 230b, the second patterned conductive layer 220b, and the third patterned conductive layer 260b may be copper or other suitable conductive metals.

FIGS. 3A-3C is a flowchart illustrating some steps in a circuit substrate manufacturing process according to another embodiment of the present invention. First, referring to FIG. 3A, two first dielectric layers 310 are disposed on a de-bonding layer 380, and two third conductive layers 330a are respectively disposed on the first dielectric layers 310 so that each of the first dielectric layers 310 is between the de-bonding layer 380 and the corresponding third conductive layer 330a. Then, referring to FIG. 3B, the third conductive layers 330a are patterned to form two first patterned conductive layers 330b. Finally, each of the first dielectric layers 310 is de-bonded from the de-bonding layer 380 to obtain a structure as illustrated in FIG. 3C. After that, the manufacturing process illustrated in FIGS. 2B-2E is carried out on this structure.

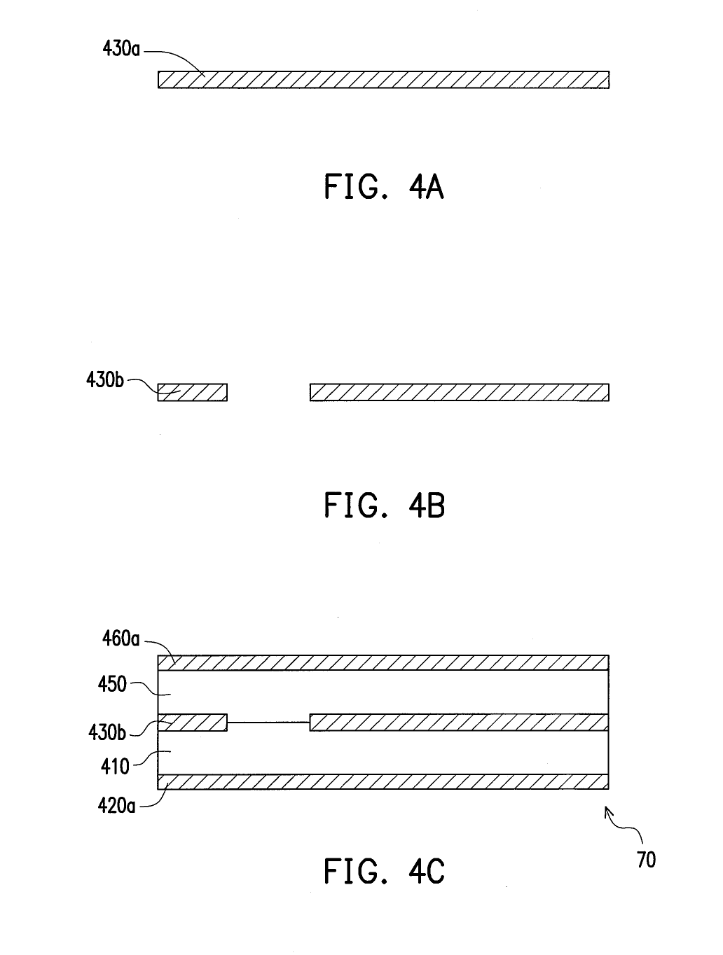

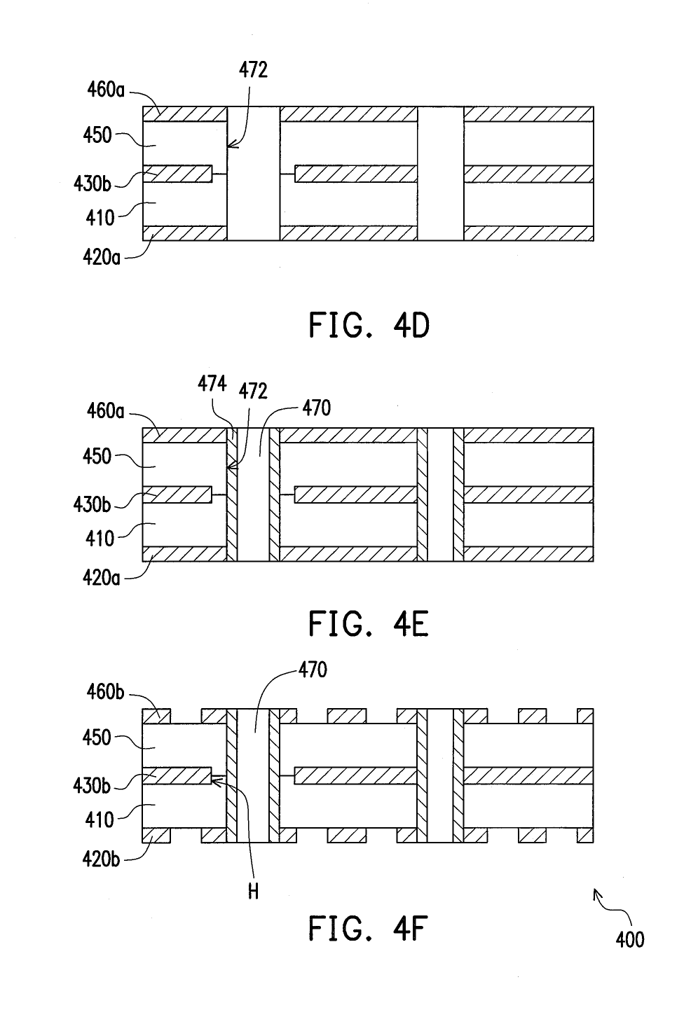

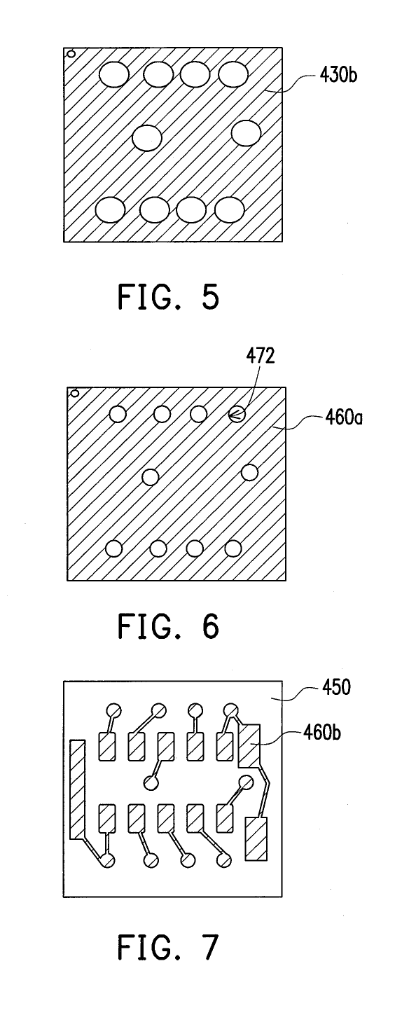

FIGS. 4A-4F is a flowchart of a circuit substrate manufacturing process according to another embodiment of the present invention, and FIG. 5, FIG. 6, and FIG. 7 are respectively top views of FIG. 4B, FIG. 4D, and FIG. 4F. First, referring to FIG. 4A, a third conductive layer 430a is provided. Referring to FIG. 4B and FIG. 5, the third conductive layer 430a is patterned through etching, pressing, or drilling to form a first patterned conductive layer 430b. referring to FIG. 4C, a first dielectric layer 410 and a first conductive layer 420a and a second dielectric layer 450 and a second conductive layer 460a are respectively formed on two opposite surfaces of the first patterned conductive layer 430b, so that the first patterned conductive layer 430b is between the first dielectric layer 410 and the second dielectric layer 450, the first dielectric layer 410 is between the first conductive layer 420a and the first patterned conductive layer 430b, and the second dielectric layer 450 is between the second conductive layer 460a and the first patterned conductive layer 430b.

A conductive structure 70 is formed through foregoing steps. The conductive structure 70 includes the first patterned conductive layer 430b, the first dielectric layer 410, the second dielectric layer 450, the first conductive layer 420a, and the second conductive layer 460a. The first dielectric layer 410 and the second dielectric layer 450 are respectively disposed on two opposite surfaces of the first patterned conductive layer 430b. The first conductive layer 420a and the second conductive layer 460a are respectively disposed on the first dielectric layer 410 and the second dielectric layer 450, wherein the first dielectric layer 410 is between the first patterned conductive layer 430b and the first conductive layer 420a, and the second dielectric layer 450 is between the first patterned conductive layer 430b and the second conductive layer 460a.

Referring to FIG. 4E, conductive vias 470 (two as illustrate) are formed at the conductive structure 70 (as shown in FIG. 4C), wherein the conductive vias 470 electrically connect at least two of the first patterned conductive layer 430b, the first conductive layer 420a, and the second conductive layer 460a. In the present embodiment, the conductive vias 470 are extended from the first conductive layer 420a to the second conductive layer 460a via the first dielectric layer 410, the first patterned conductive layer 430b, and the second dielectric layer 450 to electrically connect the first conductive layer 420a, the second conductive layer 460a, and the first patterned conductive layer 430b.

To be specific, the conductive vias 470 illustrated in FIG. 4E may be formed by first forming a through hole 472 (as shown in FIG. 4D and FIG. 6) at the conductive structure 70 (as shown in FIG. 4C) and then electroplating a metal layer 474 on the internal wall of the through hole 472. The pattern of the conductive vias 470 is not limited in the present invention, and in another embodiment, the conductive vias 470 may also be extended from the first conductive layer 420a to the first patterned conductive layer 430b via the first dielectric layer 410 but not extended to the second conductive layer 460a, so as to electrically connect the first conductive layer 420a and the first patterned conductive layer 430b. The conductive vias 470 may also be extended from the second conductive layer 460a to the first patterned conductive layer 430b via the second dielectric layer 450 but not extended to the first conductive layer 420a, so as to electrically connect the second conductive layer 460a and the first patterned conductive layer 430b.

Referring to FIG. 4F and FIG. 7, the first conductive layer 420a and the second conductive layer 460a are patterned to respectively form a second patterned conductive layer 420b and a third patterned conductive layer 460b, so as to complete the manufacturing process of a circuit substrate 400. The circuit substrate 400 includes the first patterned conductive layer 430b, the first dielectric layer 410, the second dielectric layer 450, the second patterned conductive layer 420b, the third patterned conductive layer 460b, and the conductive vias 470.

The first dielectric layer 410 and the second dielectric layer 450 are respectively disposed on two opposite surfaces of the first patterned conductive layer 430b. The second patterned conductive layer 420b and the third patterned conductive layer 460b are respectively disposed on the first dielectric layer 410 and the second dielectric layer 450, wherein the first dielectric layer 410 is between the first patterned conductive layer 430b and the second patterned conductive layer 420b, and the second dielectric layer 450 is between the first patterned conductive layer 430b and the third patterned conductive layer 460b.

The conductive vias 470 are extended from the second patterned conductive layer 420b to the third patterned conductive layer 460b via the first dielectric layer 410, the first patterned conductive layer 430b, and the second dielectric layer 450 to electrically connect the second patterned conductive layer 420b, the third patterned conductive layer 460b, and the first patterned conductive layer 230b.

To be specific, the first patterned conductive layer 430b in FIG. 4F has an opening H. One of the conductive vias 470 passes through the first patterned conductive layer 430b via the opening H and is not electrically connected to the first patterned conductive layer 430b, so that the conductive via 470 can transmit signals between the second patterned conductive layer 420b and the third patterned conductive layer 460b. The other conductive via 470 in FIG. 4F is electrically connected to the second patterned conductive layer 420b, the third patterned conductive layer 460b, and the first patterned conductive layer 230b, so that the second patterned conductive layer 420b and the third patterned conductive layer 460b can be grounded through the third patterned conductive layer 460b or heat generated on the second patterned conductive layer 420b and the third patterned conductive layer 460b can be dissipated through the third patterned conductive layer 460b.

In the present embodiment, the material of the first dielectric layer 410 and the second dielectric layer 450 may be semi-cured resin, and the material of the first patterned conductive layer 430b, the second patterned conductive layer 420b, and the third patterned conductive layer 460b may be copper or other suitable conductive metals.

In summary, in the circuit substrate manufacturing process provided by the present invention, a conductive structure having a patterned conductive layer is first provided, and then a conductive via is formed at the conductive structure and conductive layers on surfaces of the conductive structure are patterned. Thereby, the manufacturing process is simplified and the manufacturing time is shortened.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit substrate manufacturing process, comprising:
providing a conductive structure, wherein the conductive structure comprising:
a first patterned conductive layer;
a first dielectric layer and a second dielectric layer, respectively disposed on two opposite surfaces of the first patterned conductive layer;
a first conductive layer and a second conductive layer, respectively disposed on the first dielectric layer and the second dielectric layer, wherein the first dielectric layer is between the first patterned conductive layer and the first conductive layer, and the second dielectric layer is between the first patterned conductive layer and the second conductive layer;
forming a conductive via at the conductive structure, wherein the conductive via electrically connects at least two of the first patterned conductive layer, the first conductive layer, and the second conductive layer; and
patterning the first conductive layer and the second conductive layer to respectively form a second patterned conductive layer and a third patterned conductive layer.

2. The circuit substrate manufacturing process according to claim 1, wherein the step of providing the conductive structure comprises:
providing the first dielectric layer, the first conductive layer, and a third conductive layer, wherein the first conductive layer and the third conductive layer are respectively disposed on two opposite surfaces of the first dielectric layer;
forming a mask layer to cover the first conductive layer;
patterning the third conductive layer to form the first patterned conductive layer;
removing the mask layer after first patterned conductive layer is formed; and
forming the second dielectric layer and the second conductive layer on the first patterned conductive layer, so that the first patterned conductive layer is between the first dielectric layer and the second dielectric layer, and the second dielectric layer is between the second conductive layer and the first patterned conductive layer.

3. The circuit substrate manufacturing process according to claim 1, wherein the step of providing the conductive structure comprises:
providing the first dielectric layer and a third conductive layer, wherein the third conductive layer is disposed on the first dielectric layer;
patterning the third conductive layer to form the first patterned conductive layer; and
forming the first conductive layer on the first dielectric layer, and forming the second dielectric layer and the second conductive layer on the first patterned conductive layer, so that the first dielectric layer is between the first patterned conductive layer and the first conductive layer, the first patterned conductive layer is between the first dielectric layer and the second dielectric layer, and the second dielectric layer is between the first patterned conductive layer and the second conductive layer.

4. The circuit substrate manufacturing process according to claim 1, wherein the step of providing the conductive structure comprises:
providing the first patterned conductive layer; and
respectively forming the first dielectric layer and the first conductive layer and the second dielectric layer and the second conductive layer on two opposite surfaces of the first patterned conductive layer, so that the first patterned conductive layer is between the first dielectric layer and the second dielectric layer, the first dielectric layer is between the first conductive layer and the first patterned conductive layer, and the second dielectric layer is between the second conductive layer and the first patterned conductive layer.

5. The circuit substrate manufacturing process according to claim 4, wherein the step of providing the first patterned conductive layer comprises:
providing a third conductive layer; and
patterning the third conductive layer through etching, pressing, or drilling to form the first patterned conductive layer.

6. The circuit substrate manufacturing process according to claim 1, wherein the step of forming the conductive via at the conductive structure comprises:
forming a blind hole at the conductive structure, wherein the blind hole is extended from the first conductive layer to the first patterned conductive layer via the first dielectric layer; and
electroplating a metal layer on an internal wall of the blind hole to form the conductive via.

7. The circuit substrate manufacturing process according to claim 1, wherein the step of forming the conductive via at the conductive structure comprises:
forming a through hole at the conductive structure, wherein the through hole is extended from the first conductive layer to the second conductive layer via the first dielectric layer, the first patterned conductive layer, and the second dielectric layer; and
electroplating a metal layer on an internal wall of the through hole to form the conductive via.

8. The circuit substrate manufacturing process according to claim 7, wherein the first patterned conductive layer has an opening, and the conductive via passes through the first patterned conductive layer via the opening.

9. The circuit substrate manufacturing process according to claim 1, wherein a material of the first dielectric layer is cured resin or semi-cured resin.

10. The circuit substrate manufacturing process according to claim 1, wherein a material of the first patterned conductive layer is copper.
